(19) United States
(12) Patent Application Publication
(10) Pub. No.: US 2025/0261362 A1
(43) Pub. Date: Aug. 14, 2025

(54) SEMICONDUCTOR DEVICE

(71) Applicant: Samsung Electronics Co., Ltd., Suwon-si (KR)

(72) Inventors: JEONIL LEE, Suwon-si (KR); JUNHYOUNG KIM, Suwon-si (KR); JINBUM KIM, Suwon-si (KR); JINWOO HAN, Suwon-si (KR)

(21) Appl. No.: 18/820,590

(22) Filed: Aug. 30, 2024

(30) Foreign Application Priority Data
Feb. 13, 2024 (KR) 10-2024-0020666

(51) Int. Cl. H10B 12/00

(52) U.S. Cl. CPC H10B 12/482; H10B 12/315

(57) ABSTRACT

A semiconductor device may include a substrate, an insulating pattern in the substrate, a bit line extending vertically on the substrate and in contact with the insulating pattern, a transistor body portion including a first source/drain region, a channel layer, and a second source/drain region, wherein the first source/drain region is electrically connected to the bit line, gate electrode layers on an upper surface and a lower surface of the channel layer, a gate dielectric film between the gate electrode layers, and a cell capacitor electrically connected to the second source/drain region, the cell capacitor including a lower electrode layer, a capacitor dielectric film, and an upper electrode layer. The channel layer may be included in a pattern that includes oxide layers on an upper portion and a lower portion of the channel layer, respectively, and silicon nitride layers between the channel layer and the oxide layers, respectively.

### CROSS-REFERENCE TO RELATED APPLICATIONS

This application is based on and claims priority under 35 U.S.C. § 119 to Korean Patent Application No. 10-2024-0020666, filed on Feb. 13, 2024, in the Korean Intellectual Property Office, the disclosure of which is incorporated by reference herein in its entirety.

### BACKGROUND OF THE INVENTION

The inventive concepts relate to a semiconductor device, and more particularly, to a semiconductor device including a vertical channel transistor.

As electronic products become more compact, multi-functional, and have higher performance, high-capacity semiconductor memory elements may be helpful. To provide high-capacity semiconductor memory elements, increased integration is useful. The degree of integration of two-dimensional semiconductor memory elements is mainly determined by an area occupied by a unit memory cell, and thus the degree of integration of two-dimensional semiconductor memory elements is increasing but is still limited. Accordingly, a three-dimensional (3D) semiconductor memory device that increases memory capacity by stacking a plurality of memory cells in a vertical direction on a substrate has been proposed.

### SUMMARY OF THE INVENTION

The inventive concepts provide a semiconductor device with improved reliability and mechanical stability.

The objects to implement in the inventive concepts are not limited to the technical objects described above and other objects that are not stated herein will be clearly understood by those skilled in the art from the following description.

According to some aspects of the technical objects, the inventive concepts provide the following semiconductor device.

According to aspects of the inventive concepts, there is provided a semiconductor device including a substrate, an insulating pattern in the substrate, a bit line extending vertically on the substrate and in contact with the insulating pattern, a transistor body portion including a first source/drain region, a channel layer, and a second source/drain region that are arranged in a first horizontal direction, wherein the first source/drain region is electrically connected to the bit line, gate electrode layers extending in a second horizontal direction orthogonal to the first horizontal direction and on an upper surface and a lower surface of the channel layer, a gate dielectric film between the gate electrode layers, and a cell capacitor electrically connected to the second source/drain region and including a lower electrode layer, a capacitor dielectric film, and an upper electrode layer, wherein the transistor body portion is between the cell capacitor and the bit line in the first horizontal direction, and wherein the channel layer is included in a pattern that includes oxide layers on an upper portion and a lower portion of the channel layer, respectively, and silicon nitride layers between the channel layer and the oxide layers, respectively.

According to aspects of the inventive concepts, there is provided a semiconductor device including a plurality of transistor body portions that are spaced apart from each other in a vertical direction on a substrate and extend in parallel to each other in a first horizontal direction, the plurality of transistor body portions including a first source/drain region, a channel layer, and a second source/drain region that are arranged in the first horizontal direction, a plurality of bit lines that are spaced apart from each other in a second horizontal direction orthogonal to the first horizontal direction on the substrate and extend in parallel to each other in the vertical direction, wherein a respective one of the plurality of bit lines is electrically connected to the first source/drain region of at least one of the plurality of transistor body portions, a plurality of gate electrode layers that are spaced apart from each other in the vertical direction, extend in parallel to each other in the second horizontal direction, and are on at least an upper surface and a lower surface of the channel layer of at least one of the plurality of transistor body portions, a gate dielectric film between ones of the plurality of gate electrode layers, and a plurality of cell capacitors electrically connected to the second source/drain region of the plurality of transistor body portions, respectively, and including a lower electrode layer, a capacitor dielectric film, and an upper electrode layer, wherein the substrate includes an insulating pattern having an upper surface that protrudes upward beyond an upper surface of the substrate in the vertical direction, wherein the channel layer is included in a pattern that includes a pair of second material layers between a pair of first material layers and the channel layer between the pair of second material layers, and wherein the pattern is provided at least two times, and the channel layer includes single crystal silicon.

According to aspects of the inventive concepts, there is provided a semiconductor device including a plurality of transistor body portions that are spaced apart from each other in a vertical direction on a substrate and extend in parallel to each other in a first horizontal direction, the plurality of transistor body portions including a first source/drain region, a channel layer, and a second source/drain region that are arranged in the first horizontal direction, an insulating pattern in the substrate, a plurality of bit lines that are spaced apart from each other in a second horizontal direction orthogonal to the first horizontal direction on the substrate, extend in parallel to each other in the vertical direction, and are in contact with the insulating pattern, wherein a respective one of the plurality of bit lines is electrically connected to the first source/drain region of at least one of the plurality of transistor body portions, a plurality of gate electrode layers that are spaced apart from each other in the vertical direction, extend in parallel to each other in the second horizontal direction, and are on at least an upper surface and a lower surface of the channel layer of at least one of the plurality of transistor body portions, a gate dielectric film between ones of the plurality of gate electrode layers, a plurality of cell capacitors including a lower electrode layer, an upper electrode layer on the lower electrode layer, and a capacitor dielectric film between the lower electrode layer and the upper electrode layer, wherein the lower electrode layer of a respective one of the plurality of cell capacitors is electrically connected to the second source/drain region of a respective one of the plurality of transistor body portions, and wherein the lower electrode layer of the respective one of the plurality of cell capacitors has a hollow shape including a closed portion that faces the second source/drain region of the respective one of the plurality of transistor body portions and an open portion opposite to the closed portion in the first horizontal direction, an oxide layer on the channel layer, and a silicon nitride layer between the oxide layer and the channel layer, wherein the channel layer includes single crystal silicon, and an upper surface of the insulating pattern protrudes upward beyond an upper surface of the substrate in the vertical direction.

### BRIEF DESCRIPTION OF THE DRAWINGS

Example embodiments will be more clearly understood from the following detailed description taken in conjunction with the accompanying drawings, in which:

FIG. 1 is an equivalent circuit diagram showing a cell array of a semiconductor device according to embodiments;

FIGS. 2A and 2B and FIGS. 3 to 11 are diagrams showing a process sequence to explain a method of manufacturing a semiconductor device according to embodiments;

FIG. 12 is an enlarged perspective view and top view of a portion of a semiconductor device according to embodiments; and

FIG. 13 is an enlarged perspective view and cross-sectional view of a portion of a semiconductor device according to embodiments.

### DETAILED DESCRIPTION

Hereinafter, example embodiments will be described in detail with reference to the accompanying drawings. In the drawings, the same components are denoted by the same reference numerals, and a repeated explanation thereof may be omitted.

As the inventive concepts allow for various changes and numerous embodiments, particular embodiments will be illustrated in the drawings and described in detail in the following description. However, this is not intended to limit the inventive concepts to particular modes of practice, and it is to be appreciated that all changes, equivalents, and substitutes that do not depart from the technical scope of the inventive concepts are encompassed therein. In the description of embodiments, certain detailed explanations of related art may be omitted when it is deemed that they may unnecessarily obscure the essence of the inventive concepts.

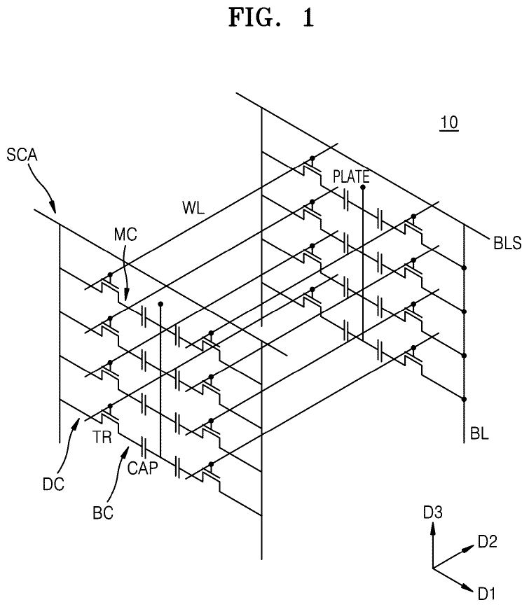

FIG. 1 is an equivalent circuit diagram showing a cell array of a semiconductor device 10 according to embodiments.

Referring to FIG. 1, the semiconductor device 10 may include a plurality of memory cells MC configured by cell transistors TR and cell capacitors CAP that are arranged in a first horizontal direction (direction D1) and are connected to each other. The plurality of memory cells MC may be arranged in a row and spaced apart from each other in the first horizontal direction (direction D1) and a vertical direction (direction D3) to form a sub-cell array SCA. The semiconductor device 10 may include a plurality of sub-cell arrays SCA spaced apart from each other in a second horizontal direction (direction D2). As used herein, “an element A connected to an element B” (or similar language) means that the element A is physically and/or electrically connected to the element B.

A plurality of word lines WL may extend in the second horizontal direction (direction D2) and may be spaced apart from each other in the first horizontal direction (direction D1) and the vertical direction (direction D3). A plurality of bit lines BL may extend in the vertical direction (direction D3) and may be spaced apart from each other in the first horizontal direction (direction D1) and the second horizontal direction (direction D2).

In some embodiments, some of the plurality of bit lines BL may be connected to each other by a bit line strapping line BLS extending in the first horizontal direction (direction D1). For example, the bit line strapping line BLS may connect ones of the bit lines BL arranged in the first horizontal direction (direction D1) from among the plurality of bit lines BL.

The plurality of cell capacitors CAP may be commonly connected to upper electrodes PLATE extending in the second horizontal direction (direction D2) and the vertical direction (direction D3). In FIG. 1, for convenience of illustration, the upper electrode PLATE is shown extending in the vertical direction (direction D3), but the upper electrodes PLATE arranged in the second horizontal direction (direction D2) may be integrated with each other.

The cell capacitor CAP and the cell transistor TR that are arranged in the first horizontal direction (direction D1) may be arranged in mirror symmetry based on a plane extending in the second horizontal direction (direction D2) and the vertical direction (direction D3), on which the upper electrodes PLATE is located.

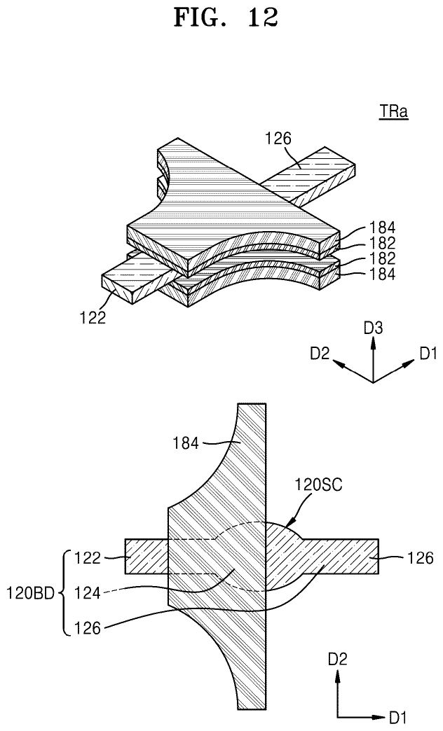

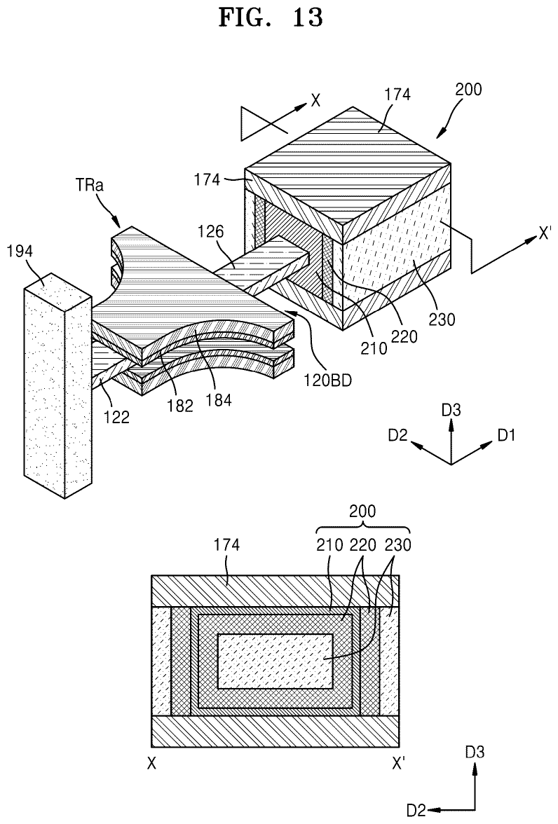

The cell transistor TR may be connected to the bit line BL through a direct contact DC and may be connected to the cell capacitor CAP through a buried contact BC. The direct contact DC may refer to a first source/drain region 122 shown in FIGS. 12 and 13, or may refer to an interface with which the first source/drain region 122 and a bit line 194 are in contact. The buried contact BC may refer to a second source/drain region 126 shown in FIGS. 12 and 13, or may refer to an interface with which the second source/drain region 126 and a lower electrode layer 210 are in contact.

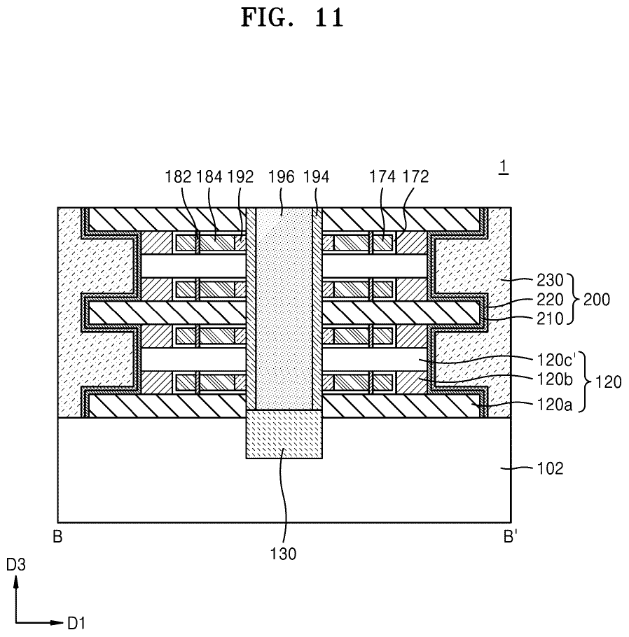

Referring to FIGS. 1, 11, 12 and 13, the semiconductor device 10 of FIG. 1 may be a semiconductor device 1 shown in FIG. 11. The cell transistor TR in FIG. 1 may be a cell transistor TRa shown in FIGS. 12 and 13. The cell capacitor CAP of FIG. 1 may be a cell capacitor 200 shown in FIGS. 11 and 13. The word line WL in FIG. 1 may be a gate electrode layer 184 shown in FIGS. 11, 12, and 13. The bit line BL in FIG. 1 may be the bit line 194 shown in FIGS. 11 and 13.

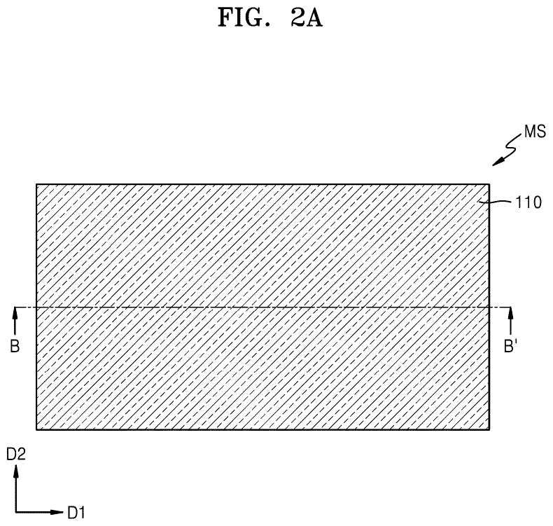

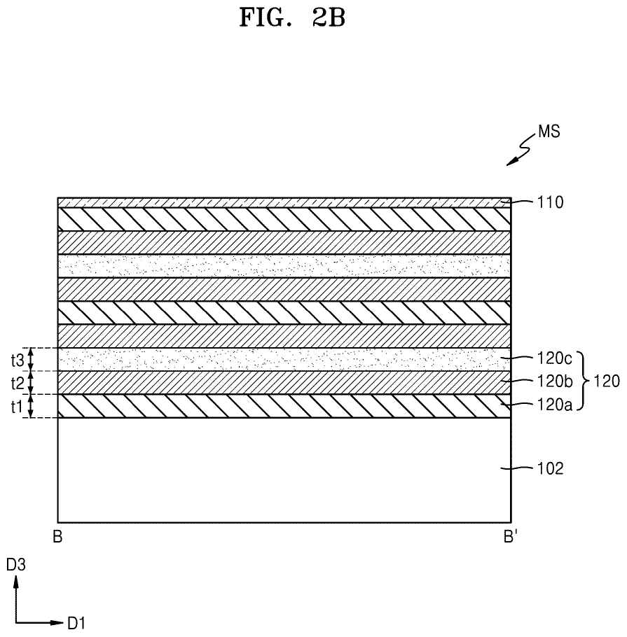

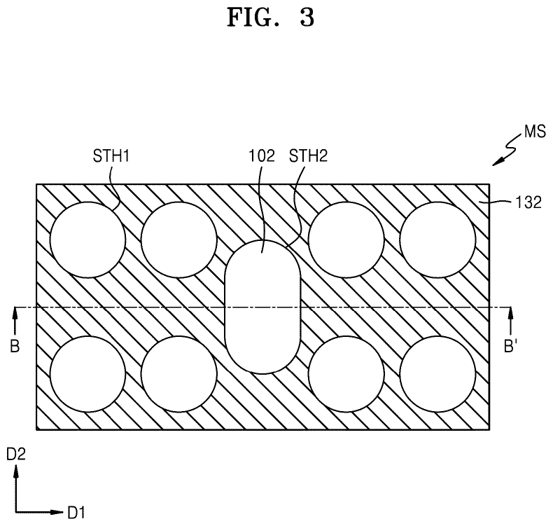

FIGS. 2A and 2B and FIGS. 3 to 11 are diagrams showing a process sequence to explain a method of manufacturing a semiconductor device 1 according to embodiments. In more detail, FIGS. 2A and 3 are plan views viewed from above, and FIGS. 2B, 4, 5, 6, 7, 8, 9, 10, and 11 are diagrams showing a cross section taken along a line B-B′ shown in FIGS. 2A and 3.

First, referring to FIGS. 2A and 2B, a multilayer structure MS, including a first material layer 120a, a second material layer 120b, a third material layer 120c, and the second material layer 120b again stacked repeatedly one by one, may be formed on a substrate 102. That is, the third material layer 120c may be located between a pair of second material layers 120b. The second material layer 120b, which is directly on an upper surface of the third material layer 120c, may have an upper surface in contact with a lower surface of the first material layer 120a. The second material layer 120b, which is directly beneath a lower surface of the third material layer 120c, may have a lower surface in contact with an upper surface of the first material layer 120a. The first material layer 120a may be located at the uppermost end of the multilayer structure MS, and an insulating film 110 may be further provided on the first material layer 120a.

According to some embodiments, referring to FIG. 2B, the multilayer structure MS is shown as a structure in which the structure described above is repeated twice, but this is merely an example and the inventive concepts are not limited thereto. For example, the multilayer structure MS may have a form in which the above structure is repeated four times.

The substrate 102 may include a single crystal semiconductor material. For example, the substrate 102 may include a silicon single crystal material. The first material layer 120a may include oxide. For example, the first material layer 120a may include silicon oxide. The second material layer 120b may include nitride. For example, the second material layer 120b may include silicon nitride. The third material layer 120c may include amorphous silicon and/or polysilicon. Unlike the substrate 102 including single crystal silicon, the third material layer 120c may not include single crystal silicon. First thicknesses t1 of the first material layers 120a in the vertical direction (direction D3) may be equal to each other. Second thicknesses t2 of the second material layers 120b in the vertical direction (direction D3) may be equal to each other. Third thicknesses t3 of the third material layers 120c in the vertical direction (direction D3) may be equal to each other. In this case, the first thicknesses t1, the second thicknesses t2, and the third thicknesses t3 may be the same or may be different from each other, and this relationship does not limit the inventive concepts. The first horizontal direction (direction D1) and the second horizontal direction (direction D2) may be parallel to a lower surface of the substrate 102, and the vertical direction (direction D3) may be perpendicular to the lower surface of the substrate 102.

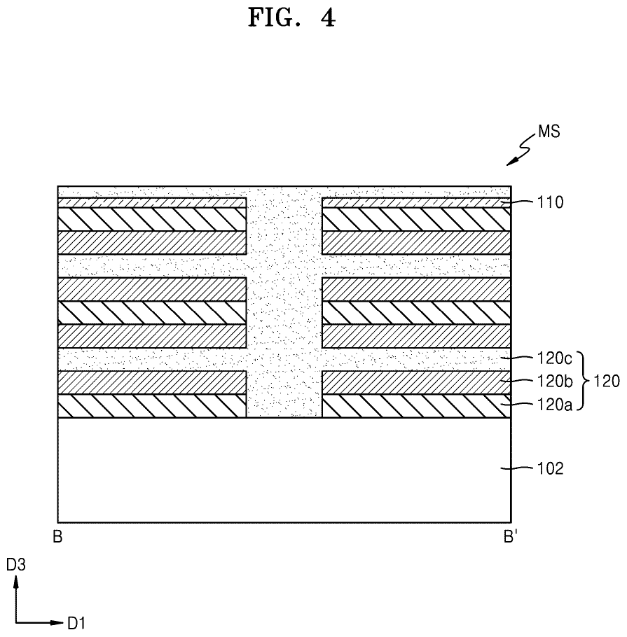

Referring to FIG. 3, after a first mask layer 132 is formed on the multilayer structure MS, a first stacked through hole STH1 and a second stacked through hole STH2 through which the substrate 102 is exposed may be formed to pass (i.e., extend) through the multilayer structure MS by using the first mask layer 132 as an etch mask. The first mask layer 132 may have a plurality of openings corresponding to the first stacked through hole STH1 and the second stacked through hole STH2. Referring to FIGS. 3 and 4, although not shown in the drawing, in some embodiments, horizontal widths of the first stacked through hole STH1 and the second stacked through hole STH2 are each tapered toward the substrate 102, but the inventive concepts are not limited thereto.

Referring to FIG. 3, the second stacked through hole STH2 may have an oval planar shape with a minor axis in the first horizontal direction (direction D1) and a major axis in the second horizontal direction (direction D2). In other words, the second stacked through hole STH2 may have a rectangular planar shape with a minor axis in the first horizontal direction (direction D1), a major axis in the second horizontal direction (direction D2), and rounded corners.

In some embodiments, the first stacked through hole STH1 may have a planar shape of a circle, an oval, a square with rounded corners, or a rectangle with rounded corners. In some embodiments, the width of the first stacked through hole STH1 in the second horizontal direction (direction D2) may be less than the width of the second stacked through hole STH2 in the second horizontal direction (direction D2), and the width of the first stacked through hole STH1 in the first horizontal direction (direction D1) and the width of the second stacked through hole STH2 in the first horizontal direction (direction D1) are substantially the same.

In embodiments, the first stacked through hole STH1 and the second stacked through hole STH2 may be spaced apart from each other in the first horizontal direction (direction D1). In embodiments, the plurality of first stacked through holes STH1 may be arranged in a row and spaced apart from each other in the second horizontal direction (direction D2) orthogonal to the first horizontal direction (direction D1).

In embodiments, the second stacked through hole STH2 may correspond to a location at which the bit line BL (refer to FIG. 1) is to be formed later.

Referring to FIG. 4, the third material layer 120c may be formed to be in (e.g., to fill) the first and second stacked through holes STH1 and STH2 (refer to FIG. 3). In some embodiments, the third material layer 120c may be formed to be in (e.g., to fill) the second stacked through hole STH2 and to be on (e.g., to cover) an upper surface of the insulating film 110 at an upper end of the multilayer structure MS. The third material layer 120c may include amorphous silicon and/or polysilicon. That is, the third material layer 120c formed in FIG. 4 may include substantially the same material as the third material layer 120c formed in FIG. 2B.

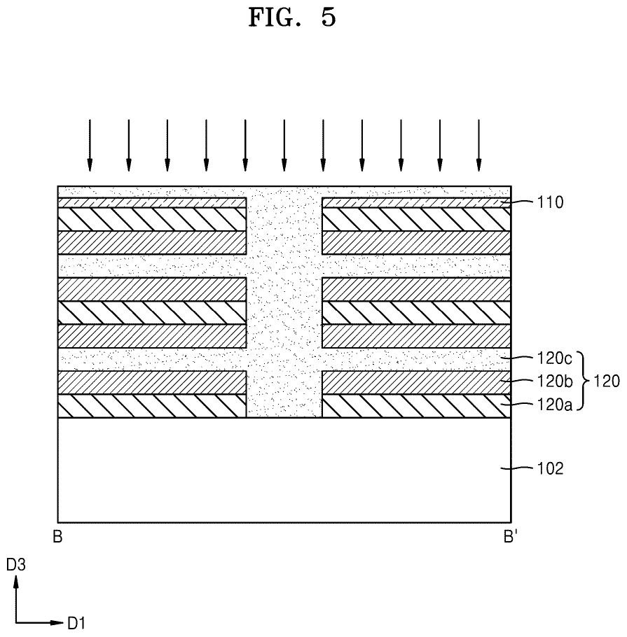

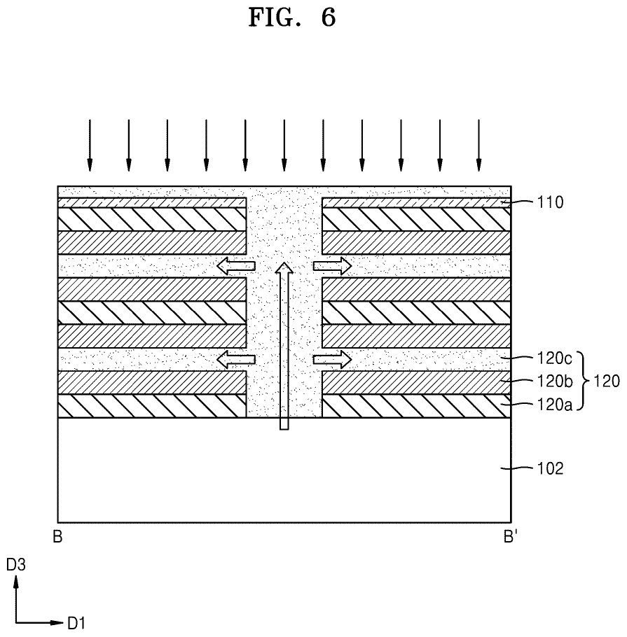

Referring to FIGS. 5 and 6, a melting process may be performed to change a crystal structure of the third material layer 120c by using a laser and/or microwave in the vertical direction (direction D3) on the multilayer structure MS. The melting process may be performed using the substrate 102 below the multilayer structure MS as a seed. In this case, the melting process may be performed in consideration of the height of the multilayer structure MS in the vertical direction (direction D3). The type of laser and/or microwave used in the melting process may be employed in various ways depending on the physical characteristics of the multilayer structure MS. The multilayer structure MS shown in FIGS. 5 and 6 has a structure in which the multilayer structure described above is repeated twice, but when the multilayer structure MS has more repeated multilayer structures, the above process may be repeated multiple times.

In some embodiments, when the multilayer structure is repeated multiple times, recrystallization of the third material layer 120c may not be achieved all at once through a melting process performed after all of the multilayer structures are formed. Therefore, in the above case, the above problem may be resolved by repeatedly performing the processes described above with reference to FIGS. 2B to 6.

In more detail, first, the multilayer structure shown in FIG. 2B may be formed again on the first material layer 120a at the uppermost end, which is exposed after the insulating film 110 at the upper end is removed from the result of FIG. 6 by using a chemical mechanical polishing (CMP) process. Then, through holes formed to pass through a newly formed multilayer structure may be formed at planarly the same location as a previously formed through holes, the newly formed through holes may be filled with the third material layer 120c (refer to FIG. 4), and a melting process to change the crystal structure of the third material layer 120c may be performed using a laser and/or microwave again in the vertical direction (direction D3) (refer to FIG. 5).

The above process may be additionally repeated multiple times as the number of repetitions of the multilayer structure increases.

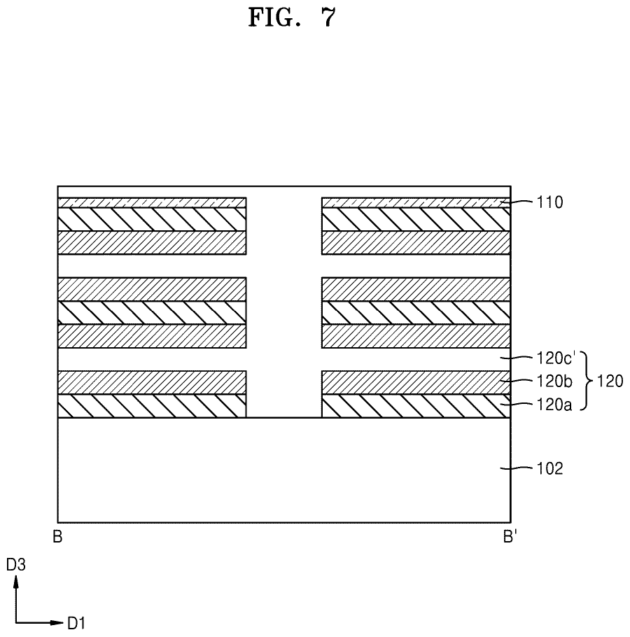

Referring to FIG. 7, the third material layer 120c stacked in the process of FIG. 2B and the third material layer 120c stacked in the process of FIG. 4 may be recrystallized through a melting process to transform a crystal structure of amorphous silicon and/or polysilicon to single crystal silicon. That is, the substrate 102 and a third material layer 120c′ may have substantially the same crystal direction. For example, the third material layer 120c including amorphous silicon and/or polysilicon may be recrystallized through the melting process using the substrate 102, which includes single crystal silicon, as a seed, and thus the third material layer 120c′ including single crystal silicon may be formed. As a result, the third material layer 120c′ may have fewer defects and improved reliability. In embodiments, the substrate 102 and the third material layer 120c′ may include a same material. For example, the substrate 102 and the third material layer 120c′ may both include single crystal silicon.

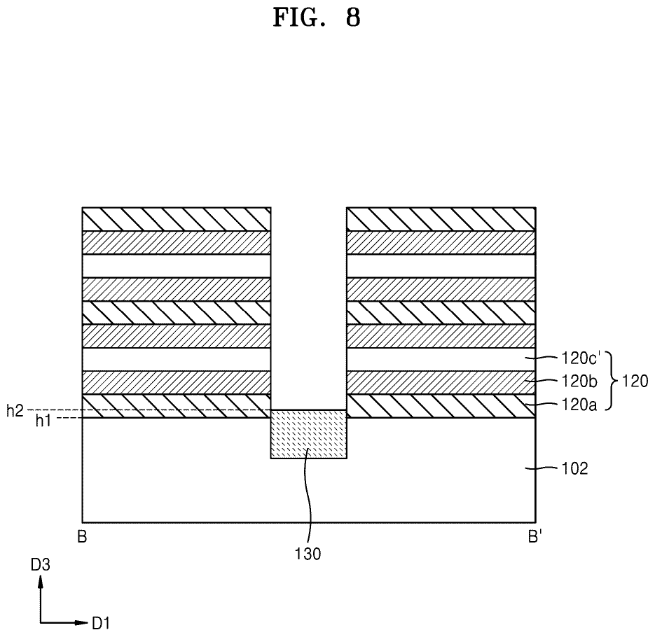

Referring to FIG. 8, a chemical mechanical polishing (CMP) process may be performed on an upper end of the multilayer structure and a process of etching the second stacked through hole STH2 filled with the third material layer 120c′ (refer to FIG. 7) may be performed to form an insulating pattern 130 on the exposed portion of the substrate 102. The insulating pattern 130 may include oxide. For example, the insulating pattern 130 may be in the substrate 102.

In embodiments, a second height h2 of the insulating pattern 130 protruding in the vertical direction (direction D3) may be greater than a first height h1, which is a level of an upper surface of the substrate 102. For example, an upper surface of the insulating pattern 130 may protrude upward beyond an upper surface of the substrate 102 in the vertical direction (direction D3). In FIG. 8, the second height h2 is shown to be greater than the first height h1, but according to other embodiments, the second height h2 may be equal to the first height h1.

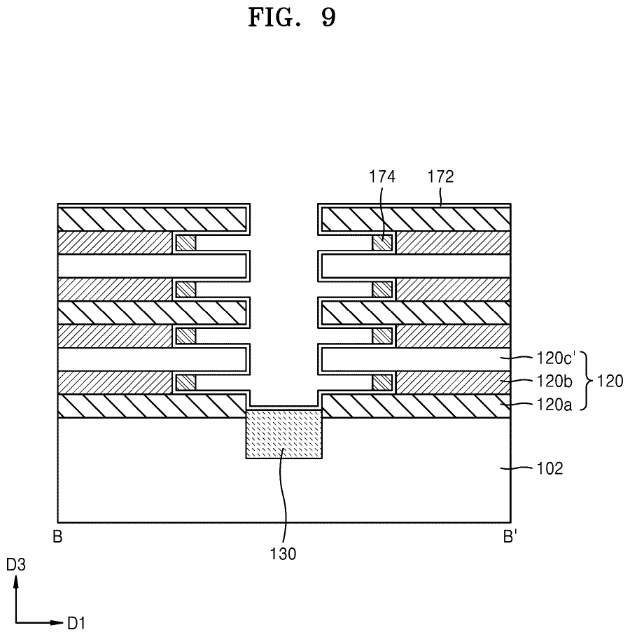

Referring to FIG. 9, a spacer liner layer 172 on (e.g., covering) an inner surface of a space between the plurality of first material layers 120a and the third material layer 120c′ that are adjacent in the vertical direction (direction D3) to exposed surfaces of the first material layer 120a, the second material layer 120b, and the third material layer 120c′ and a spacer buried layer 174 in (e.g., filling) a portion of the space may be formed by etching a portion of the second material layer 120b in FIG. 8, forming a spacer liner material layer on an exposed surface of the structure, forming a spacer buried material layer on (e.g., covering) the spacer liner material layer, and then removing a portion of the spacer liner material layer and the spacer buried material layer. In some embodiments, the spacer liner layer 172 may include silicon nitride, and the spacer buried layer 174 may include any one of silicon oxide, a silicon oxynitride film, a carbon-containing silicon oxide film, a carbon-containing silicon nitride film, or a carbon-containing silicon oxynitride film.

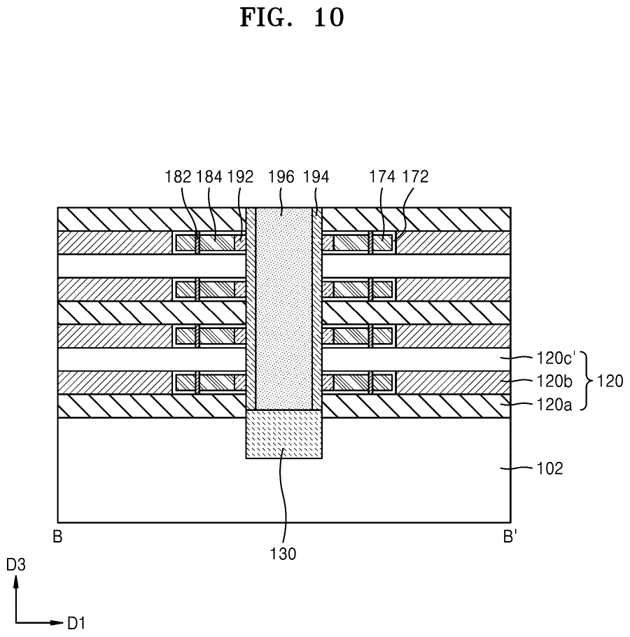

Referring to FIG. 10, a gate dielectric film 182 on (e.g., covering) the exposed surface may be formed at the location at which the spacer liner layer 172 and the spacer buried layer 174 are formed. Then, the gate electrode layer 184 may be formed to be on (e.g., to cover) the gate dielectric film 182 and to be in (e.g., to fill) an inner portion of the remaining space between the first material layer 120a and the third material layer 120c′. The gate electrode layer 184 may be formed by forming a gate electrode material layer to be on (e.g., to cover) the gate dielectric film 182 and then removing a portion of the gate electrode material layer such that the remaining portion of the gate electrode material layer remains in the inner portion of the remaining space in the vertical direction (direction D3) between the first material layer 120a and the third material layer 120c′.

The gate dielectric film 182 may include at least one selected from silicon oxide, a high-k dielectric material having a higher dielectric constant than silicon oxide, and a ferroelectric material. In some embodiments, the gate dielectric film 182 may have a multilayer structure of a first dielectric film including silicon oxide and a second dielectric film including at least one selected from a high-k dielectric material and a ferroelectric material. For example, the high-k dielectric material and the ferroelectric material may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium Titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

In some embodiments, the gate electrode layer 184 may include a conductive barrier film on (e.g., covering) the gate dielectric film 182 and a conductive filling layer on (e.g., covering) the conductive barrier film. The conductive barrier film may include, for example, metal, conductive metal nitride, conductive metal silicide, or a combination thereof. For example, the conductive barrier film may include TiN. The conductive filling layer may include, for example, doped silicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or a combination thereof. In some embodiments, the conductive filling layer may include tungsten (W).

Still referring to FIG. 10, a plurality of spacer capping layers 192 may be formed to be in (e.g., to fill) the space between the first material layer 120a and the third material layer 120c′ in the vertical direction (direction D3). In some embodiments, each of the plurality of spacer capping layers 192 may include silicon nitride. Although not shown in FIG. 10, impurities may be injected into one end of a semiconductor material layer 120 to form a plurality of first source/drain regions 122 (refer to FIG. 12).

Then, referring to FIGS. 10, 12, and 13, a plurality of bit lines 194 that are in contact with the plurality of first source/drain regions 122 and are in (e.g., fill) the space of the plurality of second stacked through holes STH2 may be formed. Then, a buried insulating layer 196 that is in (e.g., that fills) the space between the plurality of bit lines 194 and extends in the vertical direction (direction D3) may be formed.

Each of the plurality of bit lines 194 may extend in the vertical direction (direction D3) and may be in contact with the first source/drain regions 122 aligned in the vertical direction (direction D3) from among the plurality of first source/drain regions 122. Each of the plurality of bit lines 194 may extend in the vertical direction (direction D3) on the substrate 102 and may be in contact with the insulating pattern 130 that is in the substrate 102. For example, each of the plurality of bit lines 194 may include any one of a doped semiconductor such as impurity-doped silicon or impurity-doped germanium, a conductive metal nitride such as titanium nitride and tantalum nitride, metal such as tungsten, titanium, and tantalum, or metal-semiconductor compounds such as tungsten silicide, cobalt silicide, and titanium silicide. For example, the buried insulating layer 196 may include silicon oxide.

In some embodiments, each of the plurality of bit lines 194 may include a conductive barrier film in contact with the first source/drain region 122 and a conductive filling layer on (e.g., covering) the conductive barrier film. The conductive barrier film may include, for example, metal, conductive metal nitride, conductive metal silicide, or a combination thereof. For example, the conductive barrier film may include TiN. The conductive filling layer may include, for example, doped silicon, Ru, RuO, Pt, PtO, Ir, IrO, SRO (SrRuO), BSRO ((Ba,Sr)RuO), CRO (CaRuO), BaRuO, La(Sr,Co)O, Ti, TiN, W, WN, Ta, TaN, TiAlN, TiSiN, TaAlN, TaSiN, or a combination thereof. In some embodiments, the conductive filling layer may include tungsten (W).

Referring to FIG. 11, a portion of the semiconductor material layer 120 may be removed to form a recess, and the plurality of lower electrode layers 210 may be formed to be on (e.g., to cover) a surface of the recess. Then, a capacitor dielectric film 220 that is conformally on (e.g., that conformally covers) the plurality of lower electrode layers 210, and an upper electrode layer 230 that is on (e.g., that covers) the capacitor dielectric film 220 and completely fills the recess may be formed, and thus the semiconductor device 1 including the cell capacitor 200 including the lower electrode layer 210, the capacitor dielectric film 220, and the upper electrode layer 230 may be formed.

As used herein, a stack including the first material layer 120a, the second material layer 120b, the third material layer 120c′, the second material layer 120b again, and the first material layer 120a again may be referred to as a pattern. That is, the pattern may include a pair of first material layers 120a, a pair of second material layers 120b between the pair of first material layers 120a, and a third material layer 120c′ between the pair of second material layers 120b. As shown in FIG. 11, the pattern may be provided two times. In this case, one of the first material layers 120a may be shared between the two patterns. Although not shown, in some embodiments, the pattern may be provided four times. In this case, adjacent ones of the patterns may share a first material layer 120a. A channel layer 124 shown in FIG. 12 may be included in the pattern. As used herein, the channel layer 124 may be considered to include at least a portion of the third material layer 120c′. The first material layer 120a may include oxide. For example, the first material layer 120a may include silicon oxide. The second material layer 120b may include nitride. For example, the second material layer 120b may include silicon nitride. The third material layer 120c′ may include silicon. For example, the third material layer 120c′ may include single crystal silicon.

The capacitor dielectric film 220 may be on (e.g., may cover) at least a portion of inner and outer surfaces of each of the plurality of lower electrode layers 210. In some embodiments, the capacitor dielectric film 220 may be on (e.g., may cover) both the inner surface and the outer lateral surface (i.e., the outer side surface) of each of the plurality of lower electrode layers 210 (e.g., see FIGS. 11 and 13). The upper electrode layer 230 may be in (e.g., may fill) the inside of each of the plurality of lower electrode layers 210. That is, as shown in FIG. 11, each of the plurality of lower electrode layers 210 may have a U-shaped vertical cross section rotated by 90 degrees with an open portion facing an opposite side to the second source/drain region 126 (refer to FIG. 12), that is, an open portion facing the upper electrode layer 230.

The lower electrode layer 210 may include metal, conductive metal nitride, conductive metal silicide, or a combination thereof. For example, the lower electrode layer 210 may include a high-melting point metal film such as cobalt, titanium, nickel, tungsten, and molybdenum. For example, the lower electrode layer 210 may include a metal nitride film such as a titanium nitride film, a titanium silicon nitride film, a titanium aluminum nitride film, a tantalum nitride film, a tantalum silicon nitride film, a tantalum aluminum nitride film, and a tungsten nitride film.

The capacitor dielectric film 220 may include at least one selected from a high-k dielectric material having a higher dielectric constant than silicon oxide, and a ferroelectric material. For example, the capacitor dielectric film 220 may include at least one of a metal oxide or a dielectric material of a perovskite structure. In some embodiments, the capacitor dielectric film 220 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

The upper electrode layer 230 may include, for example, doped silicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or a combination thereof.

The semiconductor device 1 may include the plurality of bit lines 194 that are spaced apart from each other in the first horizontal direction (direction D1) and the second horizontal direction (direction D2) and extend in parallel to each other in the vertical direction (direction D3). A plurality of transistor body portions 120BD (refer to FIG. 12) may be spaced apart from each other in the second horizontal direction (direction D2) and the vertical direction (direction D3) and may extend in parallel to each other in the first horizontal direction (direction D1).

Referring to FIGS. 12 and 13, each of the plurality of transistor body portions 120BD may include the first source/drain region 122, a channel layer 124, and the second source/drain region 126, which are sequentially arranged in the first horizontal direction (direction D1), and the first source/drain region 122 may be connected to any one of the plurality of bit lines 194. Each of the plurality of transistor body portions 120BD may be located in the first horizontal direction (direction D1) from the bit line 194 to which the first source/drain region 122 is connected. The plurality of cell capacitors 200 may be connected to the second source/drain region 126 of the plurality of transistor body portions 120BD. The transistor body portion 120BD and the cell capacitor 200 that are connected to each other may be sequentially located in the first horizontal direction (direction D1) from the bit line 194 to which the first source/drain region 122 of the transistor body portion 120BD is connected. For example, the transistor body portion 120BD may be between the cell capacitor 200 and the bit line 194 in the first horizontal direction (direction D1). That is, the bit line 194 and the cell capacitor 200 may be located at opposite sides in the first horizontal direction (direction D1) from the connected transistor body portion 120BD. In this case, the second source/drain region 126 may be formed by injecting impurities into the other end of the semiconductor material layer 120 (refer to FIG. 11). A portion of the semiconductor material layer 120, which remains after the second source/drain region 126 is formed, may be referred to as the channel layer 124. The first source/drain region 122, the channel layer 124, and the second source/drain region 126 may be collectively referred to as the transistor body portion 120BD. The transistor body portion 120BD, the gate dielectric film 182, and the gate electrode layer 184 may constitute the cell transistors TR (refer to FIG. 1).

The semiconductor device 1 may include an information storage element connected to the second source/drain region 126. The information storage element may be a memory element for storing data. In some embodiments, the information storage element may be a cell capacitor 200.

The gate electrode layers 184 may be spaced apart from each other in the first horizontal direction (direction D1) and the vertical direction (direction D3), and may extend in parallel to each other in the second horizontal direction (direction D2). In some embodiments, the gate electrode layer 184 may have a double gate shape that is on (e.g., that covers) each of upper and lower surfaces of the channel layer 124. As used herein, the gate electrode layer 184 that has a double gate shape may also be considered to be a pair gate electrode layers 184 that form the double gate shape. Although not shown in the drawings, in some other embodiments, the gate electrode layer 184 may have a gate all around (GAA) shape that is integrally on (e.g., that integrally covers) the upper surface, lower surface, and both lateral surfaces in the second horizontal direction (direction D2) of the channel layer 124. The gate dielectric film 182 may be located between the gate electrode layer 184 and the channel layer 124. When the gate electrode layer 184 has a double gate shape, the gate dielectric film 182 may be on (e.g., may cover) each of the upper surface and the lower surface of the channel layer 124. For example, when a pair of gate electrode layers 184 form the double gate shape, the gate dielectric film 182 may be between the pair of gate electrode layers 184. When the gate electrode layer 184 has a gate all around (GAA) shape, the gate dielectric film 182 may integrally be on (e.g., may integrally cover) the upper surface, lower surface, and both lateral surfaces in the second horizontal direction (direction D2) of the channel layer 124.

Referring to FIG. 12, each of the plurality of transistor body portions 120BD may have an extension 120SC having a planar shape that protrudes convexly from an intermediate portion in the first horizontal direction (direction D1) to the second horizontal direction (direction D2). In other words, each of the plurality of transistor body portions 120BD may have an extension 120SC that protrudes in the second horizontal direction (direction D2) from an intermediate portion of each transistor body portion 120BD in the first horizontal direction (direction D1). The extension 120SC may have a relatively larger width in the second horizontal direction (direction D2) than the remaining portion of the transistor body portion 120BD. A portion of the channel layer 124 may be included in at least a portion of the extension 120SC. The extension 120SC may be at least a portion of the channel layer 124, or at least a portion of the channel layer 124 and a portion of the second source/drain region 126. A cell transistor TRa including the transistor body portion 120BD, the gate dielectric film 182, and the gate electrode layer 184 may have a channel width that substantially increases by the extension 120SC having a relatively wide width in the second horizontal direction (direction D2). However, this is merely an example, and the transistor body portion 120BD may extend in a bar shape without the extension 120SC in some other embodiments. That is, the width in the second horizontal direction (direction D2) of the channel layer 124 and/or the second source/drain region 126 may also be constant in some other embodiments.

Referring to FIGS. 12 and 13, each of the plurality of cell capacitors 200 may include the lower electrode layer 210, the capacitor dielectric film 220, and the upper electrode layer 230. The lower electrode layer 210 may be connected to the second source/drain region 126. The lower electrode layer 210 may have a hollow cylinder shape in which a portion facing the second source/drain region 126 is closed and a portion facing an opposite side to the second source/drain region 126 is open. For example, the lower electrode layer 210 may have a hollow shape including a closed portion that faces the second source/drain region 126 and an open portion opposite to the closed portion in the first horizontal direction (direction D1). The upper electrode layer 230 may be in an inner portion of the hollow shape of the lower electrode layer 210 (e.g., see FIGS. 11 and 13). The lower electrode layer 210 may have a U-shaped vertical cross-section rotated by 90 degrees with the open portion facing the upper electrode layer 230 and the closed portion facing the second source/drain region 126 (e.g., see FIG. 11).

The transistor body portion 120BD and the cell capacitor 200 may be sequentially arranged in the first horizontal direction (direction D1) from the bit line 194. The cell transistor TRa including the transistor body portion 120BD, the gate dielectric film 182, and the gate electrode layer 184, and the cell capacitor 200 including the lower electrode layer 210, the capacitor dielectric film 220, and the upper electrode layer 230 may constitute one memory cell (e.g., see the memory cell MC in FIG. 1).

The channel layer 124 of the plurality of transistor body portions 120BD provided in the semiconductor device 1 according to the inventive concepts may be a portion of the semiconductor material layer 120 shown in FIG. 11. For example, at least a portion of the channel layer 124 may correspond to the third material layer 120c′ shown in FIG. 11.

FIG. 12 is an enlarged perspective view and top view of a portion of a semiconductor device according to embodiments. Referring to FIG. 12, the cell transistor TRa may include the transistor body portion 120BD, the gate dielectric film 182, and the gate electrode layer 184. The gate electrode layer 184 may have a planar T-shape (e.g., in a plan view). For example, the gate electrode layer 184 may have a planar T-shape with a top horizontal line facing the second source/drain region 126 and a vertical line facing the first source/drain region 122. In some embodiments, the gate electrode layer 184 may have a planar T-shape that is rounded concavely between the top horizontal line and the vertical line. For example, the top horizontal line may extend in the second horizontal direction (direction D2), and the vertical line may extend in the first horizontal direction (direction D1). The gate dielectric film 182 may be located between the channel layer 124 and the gate electrode layer 184 may be on (e.g., may cover) the upper surface and lower surface of the channel layer 124.

The transistor body portion 120BD may include the first source/drain region 122, the channel layer 124, and the second source/drain region 126. The transistor body portion 120BD may include the extension 120SC having a relatively wide width in the second horizontal direction (direction D2). The extension 120SC may be a portion of the channel layer 124 and a portion of the second source/drain region 126. However, this is merely an example, and the transistor body portion 120BD may extend in a bar shape without the extension 120SC in some other embodiments. That is, the width in the second horizontal direction (direction D2) of the channel layer 124 and/or the second source/drain region 126 may also be constant in some other embodiments.

FIG. 13 is an enlarged perspective view and cross-sectional view of a portion of a semiconductor device according to embodiments. FIG. 13 illustrates the cell transistor TRa shown in FIG. 12 as an example, but the inventive concepts are not limited thereto.

Referring to FIG. 13, the memory cell may include the cell transistor TRa and the cell capacitor 200. The cross-sectional view illustrates the cell capacitor 200 taken along line X-X′ in a direction perpendicular to the first horizontal direction (direction D1) in the perspective view. In other words, the cross-sectional view is a vertical cross-section of the cell capacitor 200 taken along line X-X′.

The cell transistor TRa may include the transistor body portion 120BD, a gate dielectric film 182, and a gate electrode layer 184. The first source/drain region 122 may be connected to the bit line 194, and the second source/drain region 126 may be connected to the lower electrode layer 210.

The cell capacitors 200 may each include the lower electrode layer 210, the capacitor dielectric film 220, and the upper electrode layer 230. The capacitor dielectric film 220 and the upper electrode layer 230 may be on (e.g., may cover) an entire inner surface of the lower electrode layer 210, that is, both an inner lateral surface and an inner bottom surface, and at least a portion of an outer lateral surface of the lower electrode layer 210. The inner bottom surface of the lower electrode layer 210 refers to an inner surface of the closed portion in the hollow cylinder shape with one closed side. In other words, the capacitor dielectric film 220 and the upper electrode layer 230 may be on an inner side surface, an inner lower surface, an inner upper surface, and an outer side surface of the lower electrode layer 210. For example, when the lower electrode layer 210 has a hollow hexagonal pillar-shaped cylinder, the cell capacitor 200 may have a six-sided one cylinder stacked (OCS) shape. For example, the capacitor dielectric film 220 may be on (e.g., may cover) four inner lateral surfaces, the inner bottom surface, and the two outer surfaces opposing each other in the second horizontal direction (direction D2) of the lower electrode layer 210, and the upper electrode layers 230 may have the capacitor dielectric film 220 therebetween and may be on (e.g., may cover) four inner lateral surfaces, an inner bottom surface, and two outer lateral surfaces opposing each other in the second horizontal direction (direction D2) of the lower electrode layer 210. The cell capacitor 200 may have a six-sided OCS shape.

A manufacturing method of the semiconductor device 1 according to the inventive concepts may include, after forming a mold stack containing amorphous silicon and/or polysilicon, etching the mold stack until a silicon substrate is exposed, and depositing amorphous silicon and/or polysilicon in the etched space again. Then, a melting process may be performed using a laser and/or microwave until amorphous silicon and/or polysilicon is recrystallized into single crystal silicon. Recrystallization may be performed using a single crystal silicon substrate as a seed, and thus a silicon channel with few defects may be formed, and accordingly, a semiconductor device with excellent reliability and stability may be provided.

As above, example embodiments have been described in the drawings and specification. Although example embodiments have been described in this specification using specific terminology, this is merely used for the purpose of explaining the inventive concepts and is not used to limit the meaning or scope of the inventive concepts described in the claims. Therefore, those of skill in the art will understand that various modifications and other equivalent embodiments are possible therefrom. Therefore, the true technical scope of the inventive concepts should be determined by the claims.

While the inventive concepts have been particularly shown and described with reference to example embodiments thereof, it will be understood that various changes in form and details may be made therein without departing from the scope of the following claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor device comprising:
a substrate;
an insulating pattern in the substrate;
a bit line extending vertically on the substrate and in contact with the insulating pattern;
a transistor body portion including a first source/drain region, a channel layer, and a second source/drain region that are arranged in a first horizontal direction, wherein the first source/drain region is electrically connected to the bit line;
gate electrode layers extending in a second horizontal direction orthogonal to the first horizontal direction and on an upper surface and a lower surface of the channel layer;
a gate dielectric film between the gate electrode layers; and
a cell capacitor electrically connected to the second source/drain region and including a lower electrode layer, a capacitor dielectric film, and an upper electrode layer, wherein the transistor body portion is between the cell capacitor and the bit line in the first horizontal direction, and
wherein the channel layer is included in a pattern that comprises oxide layers on an upper portion and a lower portion of the channel layer, respectively, and silicon nitride layers between the channel layer and the oxide layers, respectively.

2. The semiconductor device of claim 1, wherein the pattern is provided at least twice.

3. The semiconductor device of claim 1, wherein the channel layer includes single crystal silicon.

4. The semiconductor device of claim 1, wherein the channel layer and the substrate include a same material.

5. The semiconductor device of claim 1, wherein the pattern is on the substrate, and one of the oxide layers is at a lowermost end of the pattern.

6. The semiconductor device of claim 1, wherein an upper surface of the insulating pattern protrudes upward beyond an upper surface of the substrate.

7. The semiconductor device of claim 1, wherein the insulating pattern includes silicon oxide.

8. The semiconductor device of claim 1, wherein the silicon nitride layers have a same thickness.

9. The semiconductor device of claim 1, wherein the oxide layers include silicon oxide.

10. The semiconductor device of claim 1, wherein the capacitor dielectric film and the upper electrode layer are on an inner side surface, an inner lower surface, and an outer side surface of the lower electrode layer.

11. The semiconductor device of claim 1, wherein the lower electrode layer has a hollow shape including a closed portion that faces the second source/drain region and an open portion opposite to the closed portion in the first horizontal direction, and
wherein the upper electrode layer is in an inner portion of the hollow shape of the lower electrode layer.

12. The semiconductor device of claim 1, wherein at least one of the gate electrode layers has a planar T-shape including a top horizontal line that faces the second source/drain region and a vertical line that faces the first source/drain region.

13. The semiconductor device of claim 1, wherein the pattern is provided four times.

14. A semiconductor device comprising:
a plurality of transistor body portions that are spaced apart from each other in a vertical direction on a substrate and extend in parallel to each other in a first horizontal direction, the plurality of transistor body portions including a first source/drain region, a channel layer, and a second source/drain region that are arranged in the first horizontal direction;
a plurality of bit lines that are spaced apart from each other in a second horizontal direction orthogonal to the first horizontal direction on the substrate and extend in parallel to each other in the vertical direction, wherein a respective one of the plurality of bit lines is electrically connected to the first source/drain region of at least one of the plurality of transistor body portions;
a plurality of gate electrode layers that are spaced apart from each other in the vertical direction, extend in parallel to each other in the second horizontal direction, and are on at least an upper surface and a lower surface of the channel layer of at least one of the plurality of transistor body portions;
a gate dielectric film between ones of the plurality of gate electrode layers; and
a plurality of cell capacitors electrically connected to the second source/drain region of the plurality of transistor body portions, respectively, and including a lower electrode layer, a capacitor dielectric film, and an upper electrode layer,
wherein the substrate includes an insulating pattern having an upper surface that protrudes upward beyond an upper surface of the substrate in the vertical direction,
wherein the channel layer is included in a pattern that comprises a pair of second material layers between a pair of first material layers and the channel layer between the pair of second material layers, and
wherein the pattern is provided at least two times, and the channel layer includes single crystal silicon.

15. The semiconductor device of claim 14, wherein the pair of first material layers include oxide, and the pair of second material layers include silicon nitride.

16. The semiconductor device of claim 14, wherein the pattern is provided four times.

17. The semiconductor device of claim 14, wherein the channel layer and the substrate include a same material.

18. The semiconductor device of claim 14, wherein the insulating pattern includes silicon oxide and is in contact with a lower portion of at least one of the plurality of bit lines.

19. The semiconductor device of claim 14, wherein each of the plurality of gate electrode layers has a planar T-shape that is rounded concavely between a top horizontal line and a vertical line of the planar T-shape.

20. A semiconductor device comprising:
a plurality of transistor body portions that are spaced apart from each other in a vertical direction on a substrate and extend in parallel to each other in a first horizontal direction, the plurality of transistor body portions including a first source/drain region, a channel layer, and a second source/drain region that are arranged in the first horizontal direction;
an insulating pattern in the substrate;
a plurality of bit lines that are spaced apart from each other in a second horizontal direction orthogonal to the first horizontal direction on the substrate, extend in parallel to each other in the vertical direction, and are in contact with the insulating pattern, wherein a respective one of the plurality of bit lines is electrically connected to the first source/drain region of at least one of the plurality of transistor body portions;
a plurality of gate electrode layers that are spaced apart from each other in the vertical direction, extend in parallel to each other in the second horizontal direction, and are on at least an upper surface and a lower surface of the channel layer of at least one of the plurality of transistor body portions;
a gate dielectric film between ones of the plurality of gate electrode layers;
a plurality of cell capacitors including a lower electrode layer, an upper electrode layer on the lower electrode layer, and a capacitor dielectric film between the lower electrode layer and the upper electrode layer, wherein the lower electrode layer of a respective one of the plurality of cell capacitors is electrically connected to the second source/drain region of a respective one of the plurality of transistor body portions, and wherein the lower electrode layer of the respective one of the plurality of cell capacitors has a hollow shape including a closed portion that faces the second source/drain region of the respective one of the plurality of transistor body portions and an open portion opposite to the closed portion in the first horizontal direction;
an oxide layer on the channel layer; and
a silicon nitride layer between the oxide layer and the channel layer,
wherein the channel layer includes single crystal silicon, and an upper surface of the insulating pattern protrudes upward beyond an upper surface of the substrate in the vertical direction.
